(19) United States
(12) Patent Application Publication
(10) Pub. No.: US 2014/0106111 A1
(43) Pub. Date: Apr. 17, 2014

(54) PHOTOCURABLE COMPOSITION AND ENCAPSULATED APPARATUS INCLUDING A BARRIER LAYER FORMED USING THE PHOTOCURABLE COMPOSITION

(71) Applicants: Seong Ryong NAM, Uiwang-si (KR); Chang Min LEE, Uiwang-si (KR); Seung Jib CHOI, Uiwang-si (KR); Ji Hye KWON, Uiwang-si (KR); Chang Soo WOO, Uiwang-si (KR); Yeon Soo LEE, Uiwang-si (KR); Kyoung Jin HA, Uiwang-si (KR)

(72) Inventors: Seong Ryong NAM, Uiwang-si (KR); Chang Min LEE, Uiwang-si (KR); Seung Jib CHOI, Uiwang-si (KR); Ji Hye KWON, Uiwang-si (KR); Chang Soo WOO, Uiwang-si (KR); Yeon Soo LEE, Uiwang-si (KR); Kyoung Jin HA, Uiwang-si (KR)

(21) Appl. No.: 14/036,392

(22) Filed: Sep. 25, 2013

(30) Foreign Application Priority Data
Oct. 11, 2012 (KR) 10-2012-0113152

(51) Int. Cl. H01L 51/52

(52) U.S. Cl. CPC H01L 51/5253
USPC 428/76; 522/64

(57) ABSTRACT

A photocurable composition, a composition for encapsulation of an organic light emitting device, an encapsulated device, and an encapsulated apparatus, the photocurable composition including a photocurable monomer; a silicon-containing monomer; and a photopolymerization initiator, wherein the silicon-containing monomer has a structure represented Formula 1:

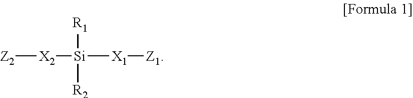

### CROSS-REFERENCE TO RELATED APPLICATION

Korean Patent Application No. 10-2012-0113152, filed on Oct. 11, 2012, in the Korean Intellectual Property Office, and entitled: “Photocurable Composition and Encapsulated Apparatus Including Barrier Layer Formed of the Same,” is incorporated by reference herein in its entirety.

### BACKGROUND

1. Field

Embodiments relate to a photocurable composition and an encapsulated apparatus including a barrier layer formed using the photocurable composition.

2. Description of the Related Art

Organic light emitting diodes (OLEDs) refer to a structure in which a functional organic material layer is between an anode and a cathode, and in which an exciton having high energy is created by recombination of a hole and an electron. The created exciton may move back to a ground state, thereby emitting light within a specific wavelength band. Organic light emitting diodes may have various merits such as self-luminance, fast response time, wide viewing angle, ultra-thinness, high definition, and durability.

### SUMMARY

Embodiments are directed to a photocurable composition and an encapsulated apparatus including a barrier layer formed using the photocurable composition.

The embodiments may be realized by providing a photocurable composition including a photocurable monomer; a silicon-containing monomer; and a photopolymerization initiator, wherein the silicon-containing monomer has a structure represented Formula 1:

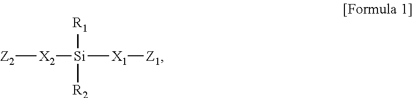

wherein, in Formula 1 X₁ and X₂ are each independently O, S, NH, or NR′, in which R′ is a C₁ to C₁₀ alkyl group, a C₃ to C₁₀ cycloalkyl group, or a C₆ to C10 aryl group; R₁ and R₂ are each independently hydrogen, a substituted or unsubstituted C₁ to C₃₀ alkyl group, a substituted or unsubstituted C₁ to C₃₀ alkyl ether group, a monoalkyl amine or dialkyl amine group having a substituted or unsubstituted C₁ to C₃₀ alkyl group, a substituted or unsubstituted C₁ to C₃₀ thioalkyl group, a substituted or unsubstituted C₆ to C₃₀ aryl group, a substituted or unsubstituted C₇ to C₃₀ arylalkyl group, a substituted or unsubstituted C₁ to C₃₀ alkoxy group, or a substituted or unsubstituted C₇ to C₃₀ arylalkoxy group; Z₁ and Z₂ are each independently hydrogen or a group represented by Formula 2:

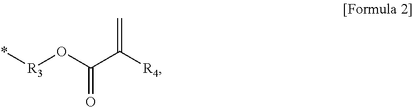

wherein, in Formula 2, * represents a binding site for X₁ or X₂ in Formula 1, R₃ is a substituted or unsubstituted C₁ to C₃₀ alkylene group, a substituted or unsubstituted C₆ to C₃₀ arylene group, or a substituted or unsubstituted C₇ to C₃₀ arylalkylene group, and R₄ is hydrogen or a substituted or unsubstituted C1 to C₃₀ alkyl group; and wherein at least one of Z₁ and Z₂ is represented by Formula 2.

The silicon-containing monomer may be represented by Formula 1, in which X₁ and X₂ may each independently be O or S; R₁ and R₂ may each independently be hydrogen, a substituted or unsubstituted C₁ to C₃₀ alkyl group, a substituted or unsubstituted C₆ to C₃₀ aryl group, or a substituted or unsubstituted C₇ to C₃₀ arylalkyl group; and Z₁ and Z₂ may each independently be hydrogen or a group represented by Formula 2:

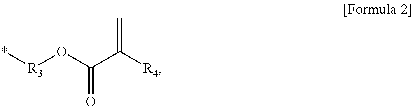

wherein * represents a binding site for X₁ or X₂ in Formula 1; R₃ is a substituted or unsubstituted C₁ to C₁₀ alkylene group; and R₄ is hydrogen or a substituted or unsubstituted C₁ to C₅ alkyl group, and wherein at least one of Z₁ and Z₂ is represented by Formula 2.

The silicon-containing monomer may include at least one monomer represented by Formula 3 or Formula 4:

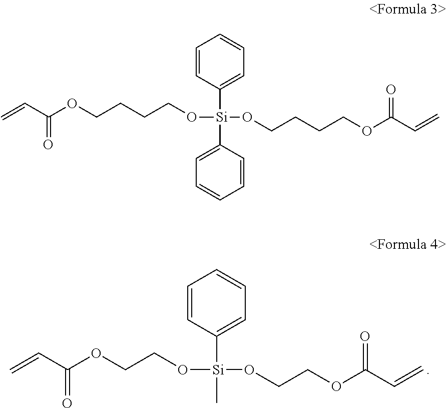

The photocurable monomer may include a monomer having 1 to about 30 substituted or unsubstituted vinyl groups, a monomer having 1 to about 30 substituted or unsubstituted acrylate groups, or a monomer having 1 to about 30 substituted or unsubstituted methacrylate groups.

The photocurable monomer may be present in the composition in an amount of about 1 to about 99 parts by weight, based on 100 parts by weight of a total weight of the photocurable monomer and the silicon-containing monomer, the silicon-containing monomer may be present in the composition in an amount of about 1 part by weight to about 99 parts by weight, based on 100 parts by weight of a total weight of the photocurable monomer and the silicon-containing monomer, and the photopolymerization initiator may be present in the composition in an amount of about 0.1 parts by weight to about 20 parts by weight, based on 100 parts by weight of a total weight of the photocurable monomer and the silicon-containing monomer.

The photocurable monomer may not contain silicon.

The embodiments may also be realized by providing a composition for encapsulation of an organic light emitting device, the composition including the photocurable composition according to an embodiment.

The embodiments may also be realized by providing an encapsulated device encapsulated with the photocurable composition according to an embodiment.

The embodiments may also be realized by providing an encapsulated apparatus including a member for the apparatus; and a barrier stack on the member for the apparatus, the barrier stack including an inorganic barrier layer and an organic barrier layer, the organic barrier layer being formed from the photocurable composition according to an embodiment, wherein the organic barrier layer has an outgas generation amount of about 1,000 ppm or less.

The encapsulated apparatus may include at least two layers of the inorganic barrier layer and the organic barrier layer.

The inorganic barrier layer may include a metal, a metalloid, a metal oxide or metalloid oxide, a metal nitride or metalloid nitride, a metal carbide or metalloid carbide, a metal oxygen nitride or metalloid oxygen nitride, a metal oxygen boride or metalloid oxygen boride, or a mixture thereof, and the metal or metalloid may include at least one selected from silicon (Si), aluminum (Al), selenium (Se), zinc (Zn), antimony (Sb), indium (In), germanium (Ge), tin (Sn), bismuth (Bi), a transition metal, or a lanthanide metal.

The organic barrier layer may have a thickness of about 0.1 μm to about 10 μm, and the inorganic barrier layer may have a thickness of about 100 Å to about 2,000 Å.

The member for the apparatus may include a flexible organic light emitting diode display, an organic light emitting diode, an illumination device, a metal sensor pad, a microdisc laser, an electrochromic device, a photochromic device, a microelectromechanical system, a solar cell, an integrated circuit, a charge coupled device, a light emitting polymer, or a light emitting diode.

The embodiments may also be realized by providing an encapsulated apparatus including a member for the apparatus; and a barrier stack on the member for the apparatus, the barrier stack including an inorganic barrier layer and an organic barrier layer, the organic barrier layer being formed from the photocurable composition according to an embodiment, wherein the organic barrier layer has a water vapor transmission rate of about 5.0 g/m²/24 hr or less, as measured at 37.8° C. and 100% relative humidity for 24 hours at a layer thickness of the organic barrier layer of 5 μm.

The encapsulated apparatus may include at least two layers of the inorganic barrier layer and the organic barrier layer.

The inorganic barrier layer may include a metal, a metalloid, a metal oxide or metalloid oxide, a metal nitride or metalloid nitride, a metal carbide or metalloid carbide, a metal oxygen nitride or metalloid oxygen nitride, a metal oxygen boride or metalloid oxygen boride, or a mixture thereof, and the metal or metalloid may include at least one selected from silicon (Si), aluminum (Al), selenium (Se), zinc (Zn), antimony (Sb), indium (In), germanium (Ge), tin (Sn), bismuth (Bi), a transition metal, or a lanthanide metal.

The organic barrier layer may have a thickness of about 0.1 μm to about 10 μm, and the inorganic barrier layer may have a thickness of about 100 Å to about 2,000 Å.

The member for the apparatus may include a flexible organic light emitting diode display, an organic light emitting diode, an illumination device, a metal sensor pad, a microdisc laser, an electrochromic device, a photochromic device, a microelectromechanical system, a solar cell, an integrated circuit, a charge coupled device, a light emitting polymer, or a light emitting diode.

### BRIEF DESCRIPTION OF DRAWINGS

Features will be apparent to those of skill in the art by describing in detail exemplary embodiments with reference to the attached drawings in which:

FIG. 1 illustrates a sectional view of an encapsulated apparatus according to an embodiment.

FIG. 2 illustrates a sectional view of an encapsulated apparatus according to another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

Unless otherwise stated, the term “substituted” as used herein may mean that at least one hydrogen atom among functional groups herein is substituted with a halogen (e.g., F, Cl, Br or I), a hydroxyl group, a nitro group, a cyano group, an imino group (e.g., ═NH, ═NR, in which R is a C₁ to C₁₀ alkyl group), an amino group [e.g., —NH₂, —NH(R′), —N(R″)(R′″), in which R′, R″ and R′″ are each independently a C₁ to C₁₀ alkyl group], an amidino group, a hydrazine or hydrazone group, a carboxyl group, a substituted or unsubstituted C₁ to C₂₀ alkyl group, a substituted or unsubstituted C₆ to C₃₀ aryl group, a substituted or unsubstituted C₃ to C₃₀ cycloalkyl group, a substituted or unsubstituted C₃ to C₃₀ heteroaryl group, or a substituted or unsubstituted C₂ to C₃₀ heterocycloalkyl group.

The term “hetero” as used herein may mean that a carbon atom is substituted with an atom selected from the group of N, O, S, and P.

An embodiment relates to a photocurable composition including, e.g., (A) a photocurable monomer; (B) a silicon-containing monomer; and (C) a photopolymerization initiator.

(A) Photocurable Monomer

The photocurable monomer may refer to a non-silicon type photocurable monomer, e.g., a photocurable monomer that does not contain silicon, and may have one or more photocurable functional groups, e.g., a (meth)acrylate group, a vinyl group, or the like.

The photocurable monomer may include, e.g., a mono-functional monomer having an unsaturated group, a polyfunctional monomer having an unsaturated group, or mixtures thereof. The photocurable monomer may include monomers having about 1 to 30 photocurable functional groups, e.g., about 1 to 20 photocurable functional groups or about 1 to 6 photocurable functional groups. The photocurable functional group may include, e.g., a substituted or unsubstituted vinyl group, a substituted or unsubstituted acrylate group, or a substituted or unsubstituted methacrylate group.

In an implementation, the photocurable monomer may include a mixture of the mono-functional monomer and the polyfunctional monomer. In such a mixture, the mono-functional monomer and the polyfunctional monomer may be present in a weight ratio of about 1:0.1 to about 1:10, e.g., from about 1:2 to about 1:3.75 (the mono-functional monomer:the polyfunctional monomer).

Examples of the photocurable monomer may include a C₆ to C₂₀ aromatic compound having a substituted or unsubstituted vinyl group; an unsaturated carboxylic acid ester (having a C₁ to C₂₀ alkyl group, a C₃ to C₂₀ cycloalkyl group, a C₆ to C₂₀ aromatic group, or a C₁ to C₂₀ alkyl group having a hydroxyl group); an unsaturated carboxylic acid ester having a C₁ to C₂₀ amino alkyl group; a vinyl ester of a C₁ to C₂₀ saturated or unsaturated carboxylic acid; a C₁ to C₂₀ unsaturated carboxylic acid glycidyl ester; a vinyl cyanide compound; an unsaturated amide compound; a (meth)acrylate of a mono-alcohol or a polyhydric alcohol; and mixtures thereof.

For example, the photocurable monomer may include, e.g., a C₆ to C₂₀ aromatic compound having an alkenyl group including a vinyl group (such as styrene, α-methyl styrene, vinyl toluene, vinyl benzyl ether, vinyl benzyl methyl ether, or the like); an unsaturated carboxylic acid ester (such as methyl(meth)acrylate, ethyl(meth)acrylate, butyl(meth)acrylate, 2-hydroxyethyl(meth)acrylate, 2-hydroxybutyl(meth)acrylate, hexyl(meth)acrylate, octyl(meth)acrylate, nonyl(meth)acrylate, decanyl(meth)acrylate, undecanyl(meth)acrylate, dodecyl(meth)acrylate, cyclohexyl(meth)acrylate, benzyl(meth)acrylate, phenyl(meth)acrylate, or the like); an unsaturated carboxylic acid amino alkyl ester (such as 2-aminoethyl(meth)acrylate, 2-dimethylaminoethyl(meth)acrylate, or the like); a saturated or unsaturated carboxylic acid vinyl ester (such as vinyl acetate, vinyl benzoate, or the like); a C₁ to C₂₀ unsaturated carboxylic acid glycidyl ester (such as glycidyl acrylate, glycidyl(meth)acrylate, or the like); a vinyl cyanide compound (such as acrylonitrile, (meth)acrylonitrile, or the like); an unsaturated amide compound (such as acrylamide, (meth)acrylamide, or the like); a monofunctional or polyfunctional (meth)acrylate of a mono-alcohol or polyhydric alcohol (such as ethylene glycol di(meth)acrylate, triethylene glycol di(meth)acrylate, trimethylolpropane tri(meth)acrylate, 1,4-butanediol di(meth)acrylate, 1,6-hexanediol di(meth)acrylate, octyldiol di(meth)acrylate, nonyldiol di(meth)acrylate, decanediol di(meth)acrylate, undecanediol di(meth)acrylate, dodecyldiol di(meth)acrylate, neopentyl glycol di(meth)acrylate, pentaerythritol di(meth)acrylate, pentaerythritol tri(meth)acrylate, pentaerythritol tetra(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A di(meth)acrylate, novolac epoxy (meth)acrylate, diethyleneglycol di(meth)acrylate, tri(propylene glycol) di(meth)acrylate, polypropylene glycol)di(meth)acrylate, or the like), without being limited thereto. The ‘polyhydric alcohol’ may refer to an alcohol having two or more hydroxyl groups, e.g., 2 to about 20 hydroxyl groups, 2 to about 10 hydroxyl groups, or 2 to about 6 hydroxyl groups.

In an implementation, the photocurable monomer may include at least one of a (meth)acrylate having a C₁ to C₂₀ alkyl group, a di(meth)acrylate of a C₂ to C₂₀ diol, a tri(meth)acrylate of a C₃ to C₂₀ triol, or a tetra(meth)acrylate of a C₄ to C₂₀ tetraol.

The photocurable monomer may be present in the composition in an amount of about 1 to about 99 parts by weight, based on 100 parts by weight of (A)+(B) (e.g., 100 parts by weight of the photocurable monomer+the silicon-containing monomer) in terms of solid content. In an implementation, the photocurable monomer may be present in an amount of about 20 to about 95 parts by weight, e.g., about 30 to about 95 parts by weight or about 60 to about 95 parts by weight. Within this range, the photocurable composition may exhibit strong resistance to plasma, thereby lowering or preventing outgas generation from plasma and/or lowering water vapor transmission rate in manufacture of thin encapsulation layers.

(B) Silicon-Containing Monomer

The silicon-containing monomer may be a silicon type or based monomer containing silicon and may have a photocurable functional group, e.g., a (meth)acrylate group, a vinyl group, or the like.

In an implementation, the silicon-containing monomer may be represented by Formula 1, below.

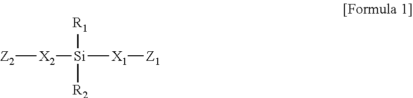

In Formula 1, X₁ and X₂ may each independently be O, S, NH, or NR′ (in which R′ may be a C₁ to C₁₀ alkyl group, a C₃ to C₁₀ cycloalkyl group, or a C₆ to C₁₀ aryl group).

R₁ and R₂ may each independently be hydrogen, a substituted or unsubstituted C₁ to C₃₀ alkyl group, a substituted or unsubstituted C₁ to C₃₀ alkyl ether group, a monoalkyl amine or dialkyl amine group having a substituted or unsubstituted C₁ to C₃₀ alkyl group, a substituted or unsubstituted C₁ to C₃₀ thioalkyl group, a substituted or unsubstituted C₆ to C₃₀ aryl group, a substituted or unsubstituted C₇ to C₃₀ arylalkyl group, a substituted or unsubstituted C₁ to C₃₀ alkoxy group, or a substituted or unsubstituted C₇ to C₃₀ arylalkoxy group.

Z₁ and Z₂ may each independently be hydrogen or a group represented by Formula 2, below.

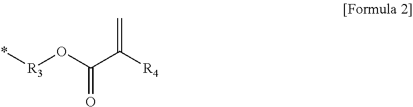

In Formula 2, “*” may represent a binding site to X₁ or X₂ of Formula 1, R₃ may be a substituted or unsubstituted C₁ to C₃₀ alkylene group, a substituted or unsubstituted C₆ to C₃₀ arylene group, or a substituted or unsubstituted C₇ to C₃₀ arylalkylene group, and R₄ may be hydrogen or a substituted or unsubstituted C₁ to C₃₀ alkyl group.

In an implementation, at least one of Z₁ and Z₂ may be represented by Formula 2.

In an implementation, the (B) silicon-containing monomer may have a structure represented by Formula 1, above, and in which X₁ and X₂ are each independently O or S; R₁ and R₂ are each independently hydrogen, a substituted or unsubstituted C₁ to C₃₀ alkyl group, a substituted or unsubstituted C₆ to C₃₀ aryl group, or a substituted or unsubstituted C₇ to C₃₀ arylalkyl group; and Z₁ and Z₂ are each independently hydrogen or a group represented by Formula 2.

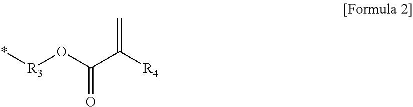

In Formula 2, “*” may represent a binding site to X₁ or X₂ of Formula 1; R₃ may be a substituted or unsubstituted C₁ to C₁₀ alkylene group; and R₄ may be hydrogen or a substituted or unsubstituted C₁ to C₅ alkyl group. In an implementation, at least one of Z₁ and Z₂ may be represented by Formula 2.

In an implementation, R₁ and R₂ may be a C₁ to C₁₀ alkyl group, a C₆ to C₂₀ aryl group, a C₁ to C₆ alkyl group, or a C₆ to C₁₀ aryl group.

In an implementation, at least one of Z₁ and Z₂ may be a group represented by Formula 2 in which R₃ is a C₁ to C₁₀ alkylene group.

In an implementation, the silicon-containing monomer may be represented by one of Formula 3 or Formula 4, below.

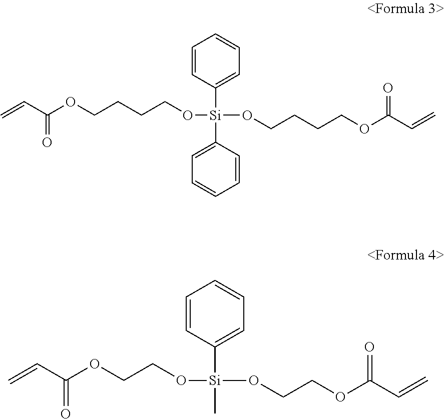

In an implementation, the silicon-containing monomer may be commercially available or may be synthesized by a suitable method.

The silicon-containing monomer included in the photocurable composition (together with the photocurable monomer) may be used to form a layer. A water vapor transmission rate and/or outgas generation amount of the layer may be remarkably reduced after curing, and a photocuring rate of the composition may be increased. In addition, due to the presence of silicon, the silicon-containing monomer included in an organic barrier layer may help minimize device damage by plasma (that may be used for deposition of an inorganic barrier layer in an encapsulation structure) when the inorganic barrier layer and the organic barrier layer are deposited.

The silicon-containing monomer may be present in the composition in an amount of about 1 part by weight to about 99 parts by weight, based on 100 parts by weight of (A)+(B). In an implementation, the silicon-containing monomer may be present in an amount of about 5 parts by weight to about 80 parts by weight, e.g., about 5 parts by weight to about 70 parts by weight or about 5 parts by weight to about 40 parts by weight. Within this range, the photocurable composition may exhibit strong resistance to plasma, thereby lowering or preventing outgas generation, e.g., due to plasma, and/or lowering water vapor transmission rate in preparation of thin encapsulation layers.

(C) Photopolymerization Initiator

The photopolymerization initiator may include a suitable photopolymerization initiator without limitation. For example, the photopolymerization initiator may include triazine, acetophenone, benzophenone, thioxanthone, benzoin, phosphorus, oxime initiators, or mixtures thereof.

Examples of the triazine initiators may include 2,4,6-trichloro-s-triazine, 2-phenyl-4,6-bis(trichloromethyl)-s-triazine, 2-(3′,4′-dimethoxystyryl)-4,6-bis(trichloro methyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloromethyl)-s-triazine, bis(trichloromethyl)-6-styryl-s-triazine, 2-(naphtho-1-yl)-4,6-bis(trichloromethyl)-s-triazine, 2-(4-methoxynaphtho-1-yl)-4,6-bis(trichloromethyl)-s-triazine, 2,4-bis(trichloromethyl)-6-(piperonyl)-s-triazine, 2,4-bis(trichloro methyl)-6-(4′-methoxystyryl)-s-triazine, or mixtures thereof.

Examples of the acetophenone initiators may include 2,2′-diethoxy acetophenone, 2,2′-dibutoxyacetophenone, 2-hydroxy-2-methylpropiophenone, p-t-butyl trichloroacetophenone, p-t-butyl dichloroacetophenone, 4-chloroacetophenone, 2,2′-dichloro-4-phenoxyacetophenone, 2-methyl-1-(4-(methylthio)phenyl)-2-morpholino propan-1-one, 2-benzyl-2-dimethylamino-1-(4-morpholinophenyl)-butan-1-one, or mixtures thereof.

Examples of the benzophenone initiators may include benzophenone, benzoyl benzoic acid, benzoyl benzoic acid methyl benzophenone, 4-phenylbenzophenone, hydroxybenzophenone, acrylated benzophenone, 4,4′-bis(dimethylamino)benzophenone, 4,4′-dichlorobenzophenone, 3,3′-dimethyl-2-methoxy benzophenone, or mixtures thereof.

Examples of the thioxanthone initiators may include thioxanthone, 2-methylthioxanthone, isopropyl thioxanthone, 2,4-diethylthioxanthone, 2,4-diisopropyl thioxanthone, 2-chlorothioxanthone, or mixtures thereof.

Examples of the benzoin initiators may include benzoin, benzoin methyl ether, benzoin ethyl ether, benzoin isopropyl ether, benzoin isobutyl ether, benzyl dimethyl ketal, or mixtures thereof.

Examples of the phosphorus initiators may include bisbenzoylphenyl phosphine oxide, benzoyldiphenyl phosphine oxide, and mixtures thereof.

Examples of the oxime initiators may include 2-(o-benzoyloxime)-1-[4-(phenylthio)phenyl]-1,2-octanedione, 1-(o-acetyloxime)-1-[9-ethyl-6-(2-methylbenzoyl)-9H-carbazole-3-yl]ethanone, or mixtures thereof.

The photopolymerization initiator may be present in the composition in an amount of about 0.1 parts by weight to about 20 parts by weight, based on 100 parts by weight of (A)+(B). Within this range, photopolymerization may be sufficiently performed under exposure to light, and an undesirable reduction in transmission (due to unreacted initiator remaining after photopolymerization) may be reduced and/or prevented. In an implementation, the photopolymerization initiator may be present in an amount of about 0.5 parts by weight to about 10 parts by weight, e.g., about 1 part by weight to about 8 parts by weight.

In an implementation, the photocurable composition may include, e.g., about 50% by weight (wt %) to about 95 wt % of (A), about 1 wt % to about 45 wt % of (B), and about 0.1 wt % to about 10 wt % of (C), in terms of solid content. Within this range, the organic barrier layer may exhibit a low water vapor transmission rate, a low outgas generation amount, and good adhesion. In an implementation, the photocurable composition may include, e.g., about 55 wt % to about 91 wt % of (A), about 4 wt % to about 40 wt % of (B), and about 1 wt % to about 5 wt % of (C).

The photocurable composition may exhibit a photocuring rate of, e.g., about 90% or more. Within this range, curing shrinkage stress after curing may be low, thereby realizing layers that do not generate any shift and facilitating their use in encapsulation applications. For example, the photocuring rate may be about 90% to about 99% or about 91% to about 97%.

The photocuring rate may be measured by a suitable method. For example, the photocurable composition may be coated onto a glass substrate and then subjected to curing at 100 mW/cm² for 10 seconds. The cured film may be cut into specimens, and the photocuring rate may be measured on the specimens using FT-IR. The photocuring rate may be calculated under conditions that are described below in the Examples.

The photocurable composition may be a composition for encapsulation of organic light emitting diodes.

A member for an apparatus, e.g., a member for a display apparatus, may suffer degradation or deterioration in quality due to introduction of gas or liquid from a surrounding environment. For example, oxygen, moisture, and/or water vapor in the atmosphere may penetrate chemical materials used in preparation of electronic products. To help reduce and/or prevent such penetration, the display apparatus may be sealed or encapsulated, and the photocurable composition according to an embodiment may be used for such sealing or encapsulation.

Examples of the member for the apparatus may include an organic light emitting diode (OLED), an illumination device, a flexible organic light emitting diode display, a metal sensor pad, a microdisc laser, an electrochromic device, a photochromic device, a microelectromechanical system, a solar cell, an integrated circuit, a charge coupled device, a light emitting polymer, a light emitting diode, or the like, without being limited thereto.

The photocurable composition may exhibit desirable properties, e.g., adhesion to an inorganic barrier layer, photocuring rate, or the like. Thus, the photocurable composition may be used for formation of organic barrier layers to be used in sealing or encapsulation for organic light emitting diodes, e.g., flexible display devices.

Another embodiment relates to an encapsulated apparatus including a member for the apparatus, and a barrier stack on the member for the apparatus. The barrier stack may include the inorganic barrier layer and the organic barrier layer, the organic barrier layer being formed from the photocurable composition. The organic barrier layer may have an outgas generation amount of about 1,000 ppm or less.

Another embodiment relates to an encapsulated apparatus including a member for the apparatus and a barrier stack on the member for the apparatus. The barrier stack may include an inorganic barrier layer and an organic barrier layer, the organic barrier layer being formed from the photocurable composition. The organic barrier layer may have a water vapor transmission rate of about 5.0 g/m² per 24 hr, or less, as measured at 37.8° C. and 100% relative humidity (RH) for 24 hours at a layer thickness of the organic barrier layer of 5 μm.

In an implementation, the encapsulated apparatus may include at least two layers of the inorganic barrier layer and the organic barrier layer.

The inorganic barrier layer may differ from the organic barrier layer in terms of components, and may help enhance the effects of the organic barrier layer.

The inorganic barrier layer may include a suitable barrier layer that exhibits good light transmittance and good moisture and/or oxygen barrier properties.

For example, the inorganic barrier layer may include a metal, a metalloid, an intermetallic compound, or an alloy. For example, the inorganic barrier layer may include an oxide of a metal, metalloid, or mixed metal, a fluoride of a metal, metalloid, or mixed metal, a nitride of a metal, metalloid, or mixed metal, a metalloid or metal carbide, an oxygen nitride (e.g., oxynitride) of a metal, metalloid, or mixed metal, a boride of a metal, metalloid, or mixed metal, an oxygen boride of a metal, metalloid, or mixed metal, a silicide of a metal, metalloid, or mixed metal, or mixtures thereof.

In an implementation, the metal or metalloid may include, e.g., silicon (Si), aluminum (Al), selenium (Se), zinc (Zn), antimony (Sb), indium (In), germanium (Ge), tin (Sn), bismuth (Bi), a transition metal, a lanthanide, or the like, without being limited thereto.

In an implementation, the inorganic barrier layer may include, e.g., silicon oxide, silicon nitride, silicon oxygen nitride, ZnSe, ZnO, Sb₂O₃, Al₂O₃, In₂O₃, or SnO₂.

The inorganic barrier layer may be deposited by vacuum processes, e.g., by sputtering, chemical vapor deposition, metal organic chemical vapor deposition, plasma chemical vapor deposition, evaporation, sublimation, electron cyclotron resonance-plasma enhanced chemical vapor deposition, or combinations thereof.

The inorganic barrier layer may have a thickness of, e.g., about 100 Å to about 2,000 Å, respectively or totally, without being limited thereto.

The organic barrier layer may exhibit little outgassing and may minimize the effects of outgassing on the devices, thereby helping to prevent performance degradation or decrease caused by outgassing. For example, the organic barrier layer may have an outgas generation amount of about 1,000 ppm or less. Within this range, the organic barrier layer may have, at most, an insignificant adverse or detrimental effect when applied to the apparatus and may help ensure a very long lifespan of the devices. In an implementation, the outgas generation amount may be about 10 ppm to about 1,000 ppm, e.g., about 200 ppm to about 870 ppm.

The outgas generation amount may be measured by a suitable method. For example, the photocurable composition may be coated onto a glass substrate and then subjected to UV curing by UV irradiation at 100 mW/cm² for 10 seconds to produce an organic barrier layer specimen having a size of 20 cm×20 cm×3 μm (width×length×thickness). For the specimen, the outgas generation amount may be determined under the conditions prescribed in the Examples, below.

The organic barrier layer may have a thickness of about 0.1 μm to about 10 μm, respectively or totally, without being limited thereto.

The organic barrier layer may have low water vapor transmission rate (WVTR) and thus may help minimize the effect of moisture on the devices. The organic barrier layer may have a water vapor transmission rate of about 5.0 g/m² per 24 hr, or less, in a thickness direction thereof. Within this range, the organic barrier layer may be used to encapsulate the devices. In an implementation, the organic barrier layer may have a water vapor transmission rate of about 1.0 to about 4.9 g/m² per 24 hr, e.g. about 2.0 to about 4.9 g/m² per 24 hr.

The water vapor transmission rate may be measured by a suitable method. For example, a photocurable composition may be coated onto an Al sample holder of a water vapor transmission rate tester (PERMATRAN-W 3/33, manufactured by MOCON) and subjected to UV curing by UV irradiation at 100 mW/cm² for 10 seconds to produce a cured specimen having a layer thickness of 5 μm. A water vapor transmission rate may be measured at 37.8° C. and 100% RH for 24 hours at a layer thickness of 5 μm.

The organic barrier layer may have an adhesive strength with respect to the inorganic barrier layer of about 20 kgf or more. Within this range, adhesive strength between the organic barrier layer and the inorganic barrier layer may be sufficiently high. Thus, an encapsulation structure may be maintained even if a physical impact is applied to devices employing the organic barrier layer, thereby ensuring that the member for the apparatus may have a long lifespan. In an implementation, the organic barrier layer may have an adhesive strength of about 20 kgf to about 50 kgf.

In an implementation, the organic barrier layer and the inorganic barrier layer may be alternately deposited. When the organic barrier layer and the inorganic barrier layer are alternately deposited, smoothing properties of the inorganic barrier layer may be secured. In addition, the organic barrier layer may help prevent a defect in the inorganic barrier layer from spreading to other regions of the inorganic barrier layer.

The barrier stack may include the organic barrier layer and the inorganic barrier layer, and a number of barrier stacks is not limited. A combination of the barrier stacks may be modified depending on a desired degree of resistance to permeation of oxygen, moisture, water vapor, and/or chemical materials.

As described above, in the barrier stack, the organic barrier layer and the inorganic barrier layer may be alternately deposited. For example, such alternate deposition may help provide a favorable effect on the organic barrier layer due to physical properties of the composition. Thus, the organic barrier layer and inorganic barrier layer may help supplement or reinforce the encapsulation effect on the member for the apparatus.

The inorganic barrier layer may be deposited by vacuum processes, e.g., by sputtering, chemical vapor deposition, plasma chemical vapor deposition, evaporation, sublimation, electron cyclotron resonance-plasma enhanced chemical vapor deposition, or combinations thereof.

The organic barrier layer may be deposited by a method similar to that of inorganic barrier layer, or may be formed by coating and curing the photocurable composition.

The apparatus may include a substrate, depending on the type of the member for the apparatus.

The substrate may include a suitable substrate that allows the member for the apparatus to be stacked thereon. Examples of the substrate may include transparent glass, plastic sheets, silicone or metal substrates, and the like.

The organic barrier layer may be stacked on the inorganic barrier layer and may include materials different from those included in the inorganic barrier layer. Thus, the organic barrier layer may supplement or reinforce the function of the inorganic barrier layer of preventing the devices from contacting external oxygen or moisture.

A pair of inorganic barrier layers and organic barrier layers may be deposited a plurality of times, e.g., two times or more, in the apparatus. In an implementation, the inorganic barrier layers and the organic barrier layers may be deposited alternately, such as in the order of inorganic barrier layer/organic barrier layer/inorganic barrier layer/organic barrier layer. In an implementation, the inorganic barrier layers and the organic barrier layers may be deposited in a total of about 10 layers or less, e.g., in a total of about 2 to 10 layers, in a total of about 7 layers or less, or in a total of about 2 to 7 layers, in the apparatus.

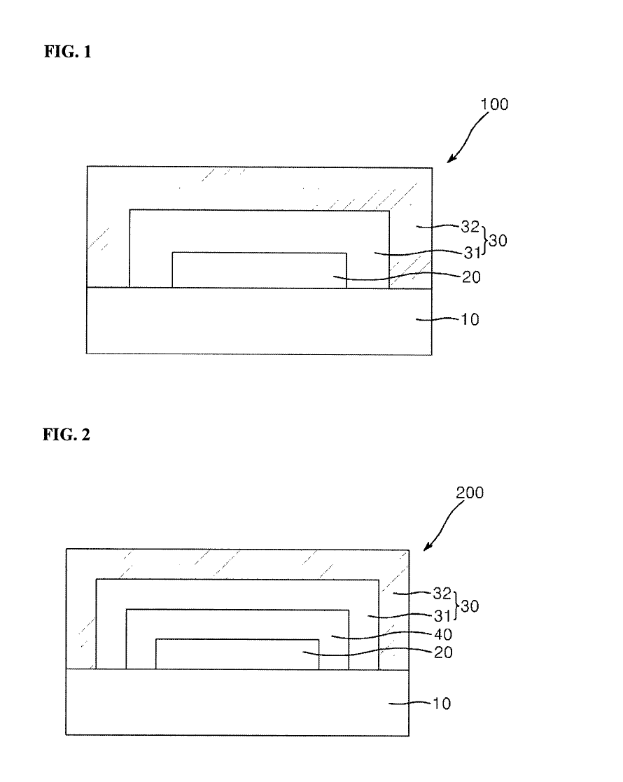

FIGS. 1 and 2 illustrate sectional views of each encapsulated apparatus according to embodiments.

Referring to FIG. 1, an encapsulated apparatus 100 may include a substrate 10, a member for the apparatus 20 on the substrate 10, and a barrier stack 30 including an inorganic barrier layer 31 and an organic barrier layer 32. The inorganic barrier layer 31 may contact the member for the apparatus 20.

Referring to FIG. 2, an encapsulated apparatus 200 may include a substrate 10, a member for the apparatus 20 on the substrate 10, and a barrier stack 30 including an inorganic barrier layer 31 and an organic barrier layer 32. The inorganic barrier layer 31 may encapsulate an interior space 40 in which the member for the apparatus 20 is received.

Although each of the inorganic barrier layer and the organic barrier layer is illustrated as being formed in a single layer in FIGS. 1 and 2, the inorganic barrier layer and the organic barrier layer may be deposited in multiple layers. In addition, the apparatus may further include a sealant and/or a substrate (not shown in FIGS. 1 and 2) on a lateral side and/or an upper side of a composite barrier layer including the inorganic barrier layer and the organic barrier layer.

The apparatus may be produced by a suitable method. Devices may be deposited on the substrate and then the inorganic barrier layer may be formed thereon. The photocurable composition may be coated to a thickness of about 1 μm to 5 μm by, e.g., deposition, spin coating, slit coating, or the like, and light may be irradiated thereto to form the organic barrier layer. The procedure of forming the inorganic barrier layer and the organic barrier layer may be repeated (e.g., 10 times or less).

In an implementation, examples of the encapsulated apparatus may include organic light emitting display devices including an organic light emitting diode, display devices including a liquid crystal display device, solar cells, and the like, without being limited thereto.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Preparative Example 1

### Preparation of a Monomer of Formula 3

A 1,000 ml flask (provided with a cooling tube and a stirrer) was filled with 400 ml of dichloromethane. Then, 68.3 g of 4-hydroxybutyl acrylate (Aldrich) and 53 g of triethylamine were introduced thereto. While stirring the reaction liquid at 0° C., 60 g of diphenyl dichlorosilane was slowly added to the flask, followed by stirring at 25° C. for four hours. After removing the dichloromethane through reduced pressure distillation, 103 g of a compound represented by Formula 3 was obtained through purification using a silica gel column. The obtained compound had a purity of 97% as measured by HPLC.

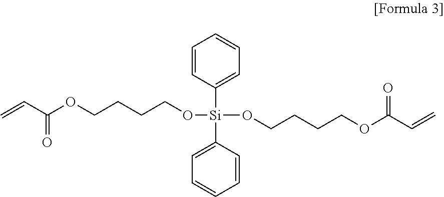 [SMILES: C=CC(=O)OCCCCO[Si](OCCCCOC(=O)C=C)(c1ccccc1)c1ccccc1]

### Preparative Example 2

### Preparation of a Monomer of Formula 4

A compound represented by Formula 4 was prepared in the same manner as in Preparative Example 1, except that phenyl methyl dichlorosilane was used instead of diphenyl dichlorosilane, and 2-hydroxyethyl acrylate was used instead of 4-hydroxybutyl acrylate. As a result, 103 g of the compound represented by Formula 4 was obtained.

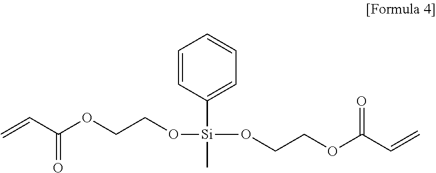 [SMILES: C=CC(=O)OCCO[Si](C)(OCCOC(=O)C=C)c1ccccc1]

Details of components used in Examples and Comparative Examples were as follows:

(A) Photocurable monomer: (A1) Hexyl acrylate, (A2) Hexanediol diacrylate, (A3) Pentaerythritol tetraacrylate (Aldrich)

(B) Silicon-containing monomer: (B1) Monomer prepared in Preparative Example 1, (B2) Monomer prepared in Preparative Example 2.

(C) Photopolymerization initiator: Darocur® TPO (BASF)

### Examples 1 to 8 and Comparative Examples 1 to 3

The (A) photocurable monomer, the (B) silicon-containing monomer, and the (C) photopolymerization initiator were placed in amounts as listed in Table 2, below, (unit: parts by weight) to a 125 ml brown polypropylene bottle, followed by blending using a shaker for 3 hours to prepare compositions.

The compositions produced in the Examples and Comparative Examples were evaluated as to physical properties. Results are shown in Table 2.

1. Water vapor transmission rate: A water vapor transmission rate tester (PERMATRAN-W 3/33, manufactured by MOCON) was employed. The photocurable composition was spray-coated onto an Al sample holder and subjected to UV curing by UV irradiation at 100 mW/cm² for 10 seconds to produce a cured specimen having a layer thickness of 5 μm. Water vapor transmission rate was measured using the water vapor transmission rate tester (PERMATRAN-W 3/33, manufactured by MOCON) at 37.8° C. and 100% RH for 24 hours at a layer thickness of 5 μm.

2. Outgas generation amount: The photocurable composition was spray-coated onto a glass substrate and subjected to UV curing by UV irradiation at 100 mW/cm² for 10 seconds to produce an organic barrier layer specimen having a size of 20 cm×20 cm×3 μm (width×length×thickness). A GC/MS tester (Perkin Elmer Clarus 600) was used to measure outgas generation. GC/MS utilized a DB-5MS column (length: 30 m, diameter: 0.25 mm, thickness of fixed phase: 0.25 μm) as a column, and helium gas (flow rate: 1.0 mL/min, average velocity=32 cm/s) as a mobile phase. Further, the split ratio was 20:1 and the temperature condition was set such that temperature was maintained at 40° C. for 3 minutes, heated at a rate of 10° C./minute, and then maintained at 320° C. for 6 minutes. Outgas was collected under the conditions that a glass size was 20 cm×20 cm, the collection container was a Tedlar® bag, the collection temperature was 90° C., the collection time was 30 minutes, N₂ purging was conducted at a flow rate of 300 mL/minute and the adsorbent was Tenax® GR (5% phenylmethyl polysiloxane). A calibration curve was plotted using a toluene solution in n-hexane in a concentration of 150 ppm, 400 ppm, and 800 ppm as a standard solution, wherein R2 value was 0.9987. The conditions mentioned above are summarized in Table 1, below.

TABLE 1

| Conditions | Details | |
|---|---|---|
| Collection | Glass size: 20 cm × 20 cm | |
| conditions | Collection container: Tedlar ® bag | |
| | Collection temperature: 90° C. | |
| | Collection time: 30 min | |
| | N₂ purge flow rate: 300 mL/min | |
| | Adsorbent: Tenax ® GR | |
| Conditions for | Standard solution: Toluene in n-hexane | |
| plotting | Concentration range: 150 ppm, 400 ppm, 800 ppm | |
| calibration | R2: 0.9987 | |
| curve | | |
| GC/MS | Column | DB-5MS→30 m × 0.25 mm × 0.25 μm |
| conditions | | (5% phenylmethyl polysiloxane) |
| | Mobile | He |
| | phase | |
| | Flow | 1.0 mL/min (Average velocity = 32 cm/s) |
| | Split | Split ratio = 20:1 |
| | Method | 40° C. (3 min)-10° C./min→ 320° C. (6 |
| | | min) |

3. Photocuring rate: An intensity of absorption peaks for the photocurable composition were measured using FT-IR (NICOLET 4700, Thermo) near 1,635 cm⁻¹ (C═C) and 1,720 cm⁻¹ (C═O). First, the photocurable composition was spray-coated onto a glass substrate and then subjected to UV curing by UV irradiation at 100 mW/cm² for 10 seconds to produce a specimen having a size of 20 cm×20 cm×3 μm (width×length×thickness). The cured film was cut into specimens, which in turn were used to measure the intensity of absorption peaks near 1,635 cm⁻¹ (C═C) and 1,720 cm⁻¹ (C═O) using FT-IR (NICOLET 4700, by Thermo). The photocuring rate was calculated by Equation 1:

Photocuring rate(%)=|1−(A/B)|×100 Equation 1

In Equation 1, A is a ratio of the intensity of absorption peak near 1,635 cm⁻¹ to the intensity of absorption peak near 1,720 cm⁻¹ on the cured film, and B is a ratio of the intensity of absorption peak near 1,635 cm⁻¹ to the intensity of absorption peak near 1,720 cm⁻¹ on the photocurable composition.

4. Adhesive strength (kgf): To measure an adhesive strength between glass sheets, the same method as a method for measuring die shear strength was used. An upper glass was pushed from a lateral side by a force of 200 kgf at 25° C., and a force at the moment of detachment thereof was measured using a Dage Series 4000PXY, which is an adhesive strength tester. A lower glass had a size of 2 cm×2 cm×1 mm (width×length×thickness), the upper glass had a size of 1.5 cm×1.5 cm×1 mm (width×length×thickness), and an adhesive layer had a thickness of 500 μm.

TABLE 2

| | | Example | | | | | | | | Comparative Example | | |
|---|---|---|---|---|---|---|---|---|---|---|---|---|
| | | 1 | 2 | 3 | 4 | 5 | 6 | 7 | 8 | 1 | 2 | 3 |
| A | A1 | 20 | 20 | 20 | 20 | 20 | 20 | 20 | 20 | 20 | 20 | 20 |
| | A2 | 40 | 60 | 70 | 70 | 40 | 60 | 70 | 70 | 40 | 60 | 70 |
| | A3 | — | — | — | 5 | — | — | — | 5 | 40 | 20 | 10 |
| B | B1 | 40 | 20 | 10 | 5 | — | — | — | — | — | — | — |
| | B2 | — | — | — | — | 40 | 20 | 10 | 5 | — | — | — |

| | | | | | | | | | | | |
|---|---|---|---|---|---|---|---|---|---|---|---|
| C | 5 | 5 | 5 | 5 | 5 | 5 | 5 | 5 | 5 | 5 | 5 |
| Water vapor transmission | 2.0 | 2.7 | 3.5 | 4.9 | 2.3 | 3.1 | 3.5 | 4.1 | 6.8 | 7.7 | 9.4 |
| rate (g/m² · 24 hr) | | | | | | | | | | | |
| Outgas generation amount | 230 | 250 | 380 | 870 | 210 | 230 | 280 | 340 | 13200 | 1510 | 2780 |
| (ppm) | | | | | | | | | | | |
| Photo curing rate (%) | 96.1 | 93.4 | 92.1 | 91.5 | 96.3 | 96.0 | 95.2 | 94.5 | 83 | 87.5 | 89.2 |
| Adhesive strength (kgf) | 38.1 | 33.3 | 23.8 | 21.2 | 42.5 | 36.5 | 29.1 | 26.3 | 14.8 | 13.5 | 11.5 |

As may be seen in Table 2, the layers formed of the photocurable compositions according to Examples demonstrated low water vapor transmission rate, significantly reduced outgas generation amount, a significantly high photocuring rate, and a high adhesive strength.

The layers formed of the photocurable compositions according to Comparative Examples 1 to 3, which did not include a silicon-containing monomer, demonstrated high water vapor transmission rate, high outgas generation amount, a low photocuring rate, and a low adhesive strength. As such, the layers were less suitable regarding the beneficial effects described above.

By way of summation and review, moisture, oxygen, or other materials may enter an OLED from outside or due to outgassing inside or outside the OLEDs, despite sealing. Thus, organic materials and/or electrode materials may be oxidized, causing deterioration in the performance and lifespan thereof. Coating with a photocurable sealing agent, attachment of a transparent or opaque moisture absorbent, or provision of fits to a substrate on which an organic light emitting part is formed may thus be used.

For example, an encapsulated structure of organic light emitting diode devices may include a protective membrane for encapsulation formed of a moisture penetration inhibiting silicone compound or polymer resin.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photocurable composition, comprising:
a photocurable monomer;
a silicon-containing monomer; and
a photopolymerization initiator,
wherein the silicon-containing monomer has a structure represented Formula 1: 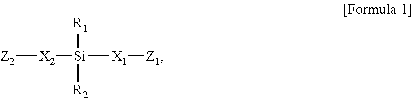
wherein, in Formula 1:
X₁ and X₂ are each independently O, S, NH, or NR′, in which R′ is a C₁ to C₁₀ alkyl group, a C₃ to C₁₀ cycloalkyl group, or a C₆ to C10 aryl group;
R₁ and R₂ are each independently hydrogen, a substituted or unsubstituted C₁ to C₃₀ alkyl group, a substituted or unsubstituted C₁ to C₃₀ alkyl ether group, a monoalkyl amine or dialkyl amine group having a substituted or unsubstituted C₁ to C₃₀ alkyl group, a substituted or unsubstituted C₁ to C₃₀ thioalkyl group, a substituted or unsubstituted C₆ to C₃₀ aryl group, a substituted or unsubstituted C₇ to C₃₀ arylalkyl group, a substituted or unsubstituted C₁ to C₃₀ alkoxy group, or a substituted or unsubstituted C₇ to C₃₀ arylalkoxy group;
Z₁ and Z₂ are each independently hydrogen or a group represented by Formula 2: 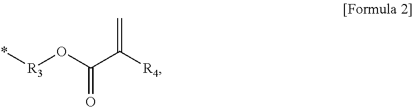
wherein, in Formula 2, * represents a binding site for X₁ or X₂ in Formula 1, R₃ is a substituted or unsubstituted C₁ to C₃₀ alkylene group, a substituted or unsubstituted C₆ to C₃₀ arylene group, or a substituted or unsubstituted C₇ to C₃₀ arylalkylene group, and R₄ is hydrogen or a substituted or unsubstituted C1 to C₃₀ alkyl group; and
wherein at least one of Z₁ and Z₂ is represented by Formula 2.

2. The photocurable composition as claimed in claim 1, wherein the silicon-containing monomer is represented by Formula 1, in which X₁ and X₂ are each independently O or S; R₁ and R₂ are each independently hydrogen, a substituted or unsubstituted C₁ to C₃₀ alkyl group, a substituted or unsubstituted C₆ to C₃₀ aryl group, or a substituted or unsubstituted C₇ to C₃₀ arylalkyl group; and Z₁ and Z₂ are each independently hydrogen or a group represented by Formula 2: 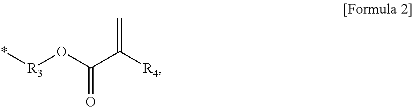
wherein * represents a binding site for X₁ or X₂ in Formula 1; R₃ is a substituted or unsubstituted C₁ to C₁₀ alkylene group; and R₄ is hydrogen or a substituted or unsubstituted C₁ to C₅ alkyl group, and
wherein at least one of Z₁ and Z₂ is represented by Formula 2.

3. The photocurable composition as claimed in claim 2, wherein the silicon-containing monomer includes at least one monomer represented by Formula 3 or Formula 4:

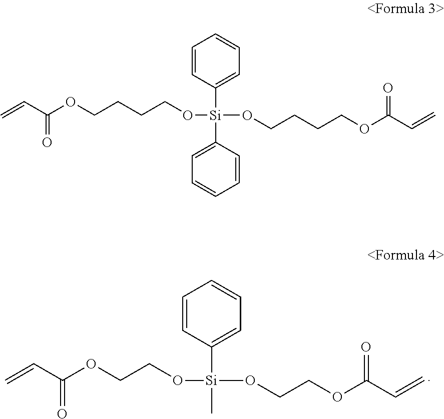

4. The photocurable composition as claimed in claim 1, wherein the photocurable monomer includes a monomer having 1 to about 30 substituted or unsubstituted vinyl groups, a monomer having 1 to about 30 substituted or unsubstituted acrylate groups, or a monomer having 1 to about 30 substituted or unsubstituted methacrylate groups.

5. The photocurable composition as claimed in claim 1, wherein:
the photocurable monomer is present in the composition in an amount of about 1 to about 99 parts by weight, based on 100 parts by weight of a total weight of the photocurable monomer and the silicon-containing monomer,
the silicon-containing monomer is present in the composition in an amount of about 1 part by weight to about 99 parts by weight, based on 100 parts by weight of a total weight of the photocurable monomer and the silicon-containing monomer, and
the photopolymerization initiator is present in the composition in an amount of about 0.1 parts by weight to about 20 parts by weight, based on 100 parts by weight of a total weight of the photocurable monomer and the silicon-containing monomer.

6. The photocurable composition as claimed in claim 1, wherein the photocurable monomer does not contain silicon.

7. A composition for encapsulation of an organic light emitting device, the composition including the photocurable composition as claimed in claim 1.

8. An encapsulated device encapsulated with the photocurable composition as claimed in claim 1.

9. An encapsulated apparatus, comprising:
a member for the apparatus; and
a barrier stack on the member for the apparatus, the barrier stack including an inorganic barrier layer and an organic barrier layer, the organic barrier layer being formed from the photocurable composition as claimed in claim 1,
wherein the organic barrier layer has an outgas generation amount of about 1,000 ppm or less.

10. The encapsulated apparatus as claimed in claim 9, wherein the encapsulated apparatus includes at least two layers of the inorganic barrier layer and the organic barrier layer.

11. The encapsulated apparatus as claimed in claim 9, wherein:
the inorganic barrier layer includes a metal, a metalloid, a metal oxide or metalloid oxide, a metal nitride or metalloid nitride, a metal carbide or metalloid carbide, a metal oxygen nitride or metalloid oxygen nitride, a metal oxygen boride or metalloid oxygen boride, or a mixture thereof, and
the metal or metalloid includes at least one selected from silicon (Si), aluminum (Al), selenium (Se), zinc (Zn), antimony (Sb), indium (In), germanium (Ge), tin (Sn), bismuth (Bi), a transition metal, or a lanthanide metal.

12. The encapsulated apparatus as claimed in claim 9, wherein:
the organic barrier layer has a thickness of about 0.1 μm to about 10 μm, and
the inorganic barrier layer has a thickness of about 100 Å to about 2,000 Å.

13. The encapsulated apparatus as claimed in claim 9, wherein the member for the apparatus includes a flexible organic light emitting diode display, an organic light emitting diode, an illumination device, a metal sensor pad, a microdisc laser, an electrochromic device, a photochromic device, a microelectromechanical system, a solar cell, an integrated circuit, a charge coupled device, a light emitting polymer, or a light emitting diode.

14. An encapsulated apparatus, comprising:
a member for the apparatus; and
a barrier stack on the member for the apparatus, the barrier stack including an inorganic barrier layer and an organic barrier layer, the organic barrier layer being formed from the photocurable composition as claimed in claim 1,
wherein the organic barrier layer has a water vapor transmission rate of about 5.0 g/m²/24 hr or less, as measured at 37.8° C. and 100% relative humidity for 24 hours at a layer thickness of the organic barrier layer of 5 μm.

15. The encapsulated apparatus as claimed in claim 14, wherein the encapsulated apparatus includes at least two layers of the inorganic barrier layer and the organic barrier layer.

16. The encapsulated apparatus as claimed in claim 14, wherein:
the inorganic barrier layer includes a metal, a metalloid, a metal oxide or metalloid oxide, a metal nitride or metalloid nitride, a metal carbide or metalloid carbide, a metal oxygen nitride or metalloid oxygen nitride, a metal oxygen boride or metalloid oxygen boride, or a mixture thereof, and
the metal or metalloid includes at least one selected from silicon (Si), aluminum (Al), selenium (Se), zinc (Zn), antimony (Sb), indium (In), germanium (Ge), tin (Sn), bismuth (Bi), a transition metal, or a lanthanide metal.

17. The encapsulated apparatus as claimed in claim 14, wherein:
the organic barrier layer has a thickness of about 0.1 μm to about 10 μm, and
the inorganic barrier layer has a thickness of about 100 Å to about 2,000 Å.

18. The encapsulated apparatus as claimed in claim 14, wherein the member for the apparatus includes a flexible organic light emitting diode display, an organic light emitting diode, an illumination device, a metal sensor pad, a microdisc laser, an electrochromic device, a photochromic device, a microelectromechanical system, a solar cell, an integrated circuit, a charge coupled device, a light emitting polymer, or a light emitting diode.
